(19) United States
(12) Patent Application Publication
(10) Pub. No.: US 2016/0104718 A1
(43) Pub. Date: Apr. 14, 2016

(54) METHOD FOR MANUFACTURING SEMICONDUCTOR DEVICE

(71) Applicant: KABUSHIKI KAISHA TOSHIBA, Tokyo (JP)

(72) Inventors: Mitsuhiro OMURA, Kuwana (JP); Kazuhito Furumoto, Yokkaichi (JP)

(73) Assignee: KABUSHIKI KAISHA TOSHIBA

(21) Appl. No.: 14/616,812

(22) Filed: Feb. 9, 2015

Related U.S. Application Data
(60) Provisional application No. 62/062,209, filed on Oct. 10, 2014.

(51) Int. Cl. H01L 27/115; H01L 21/28; H01L 21/311

(52) U.S. Cl. CPC H01L 27/11582; H01L 27/11556; H01L 21/31116; H01L 21/31144; H01L 21/31122; H01L 21/28282; H01L 21/28273

(57) ABSTRACT

According to one embodiment, a method for manufacturing a semiconductor device includes etching an etching target layer under a mask layer using a first gas. The mask layer includes a plurality of first layers, one or more second layers, and a mask hole piercing through the plurality of first layers and the one or more second layers. The method includes etching an outermost first layer exposed to an outermost layer of the mask layer among the plurality of first layers using a second gas, and exposing a layer directly under the outermost first layer. The etching using the first gas and the etching using the second gas are repeated to form a hole in the etching target layer.

### CROSS-REFERENCE TO RELATED APPLICATION

This application is based upon and claims the benefit of priority from U.S. Provisional Patent Application 62/062,209, filed on Oct. 10, 2014; the entire contents of which are incorporated herein by reference.

### FIELD

Embodiments described herein relate generally to a method for manufacturing a semiconductor device.

### BACKGROUND

There has been proposed a three-dimensional structure memory device. The memory device has a stacked body formed by stacking, via insulating layers, a plurality of electrode layers functioning as control gates in memory cells. A memory hole is formed in the stacked body. A silicon body functioning as a channel is provided on a sidewall of the memory hole via a charge storage film.

In such a memory cell array having the three-dimensional structure, when the number of stacked layers of the electrode layers increases according to an increase in a storage capacity and an aspect ratio of the memory hole increases, it tends to be difficult to form a hole having high circularity at a uniform diameter over a stacking direction of the electrode layers.

### BRIEF DESCRIPTION OF THE DRAWINGS

FIG. 1 is a schematic perspective view of a semiconductor device of an embodiment;

FIG. 2 is an enlarged schematic sectional view of a part of the semiconductor device of the embodiment;

FIGS. 3 to 28 are schematic views showing a method for manufacturing the semiconductor device of the embodiment; and

FIG. 29 is a schematic cross-sectional view showing an asymmetrical erosion of a mask layer.

### DETAILED DESCRIPTION

According to one embodiment, a method for manufacturing a semiconductor device includes etching an etching target layer under a mask layer using a first gas, the mask layer including a plurality of first layers, one or more second layers including a second layer provided between adjacent first layers and having a material different from a material of the first layers, and a mask hole piercing through the plurality of first layers and the one or more second layers. The method includes etching an outermost first layer exposed to an outermost layer of the mask layer among the plurality of first layers using a second gas, and exposing a layer directly under the outermost first layer. The etching using the first gas and the etching using the second gas are repeated to form a hole in the etching target layer.

Embodiments are described with reference to the drawings. Note that, in the drawings, the same components are denoted by the same reference numerals and signs.

In the embodiment, for example, a semiconductor memory device including a memory cell array having a three-dimensional structure is described as a semiconductor device.

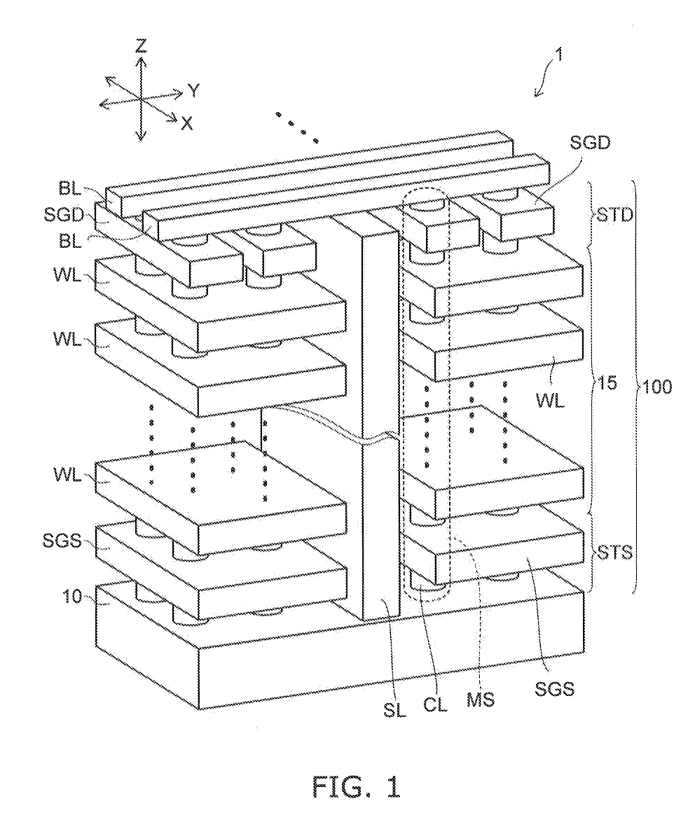

FIG. 1 is a schematic perspective view of a memory cell array 1 of the embodiment. In FIG. 1, illustration of insulating layers is omitted to clearly show the figure.

In FIG. 1, two directions parallel to the major surface of a substrate 10 and orthogonal to each other are represented as an X-direction (a first direction) and a Y-direction (a second direction). A direction orthogonal to both of the X-direction and the Y-direction is represented as a Z-direction (a third direction or a stacking direction).

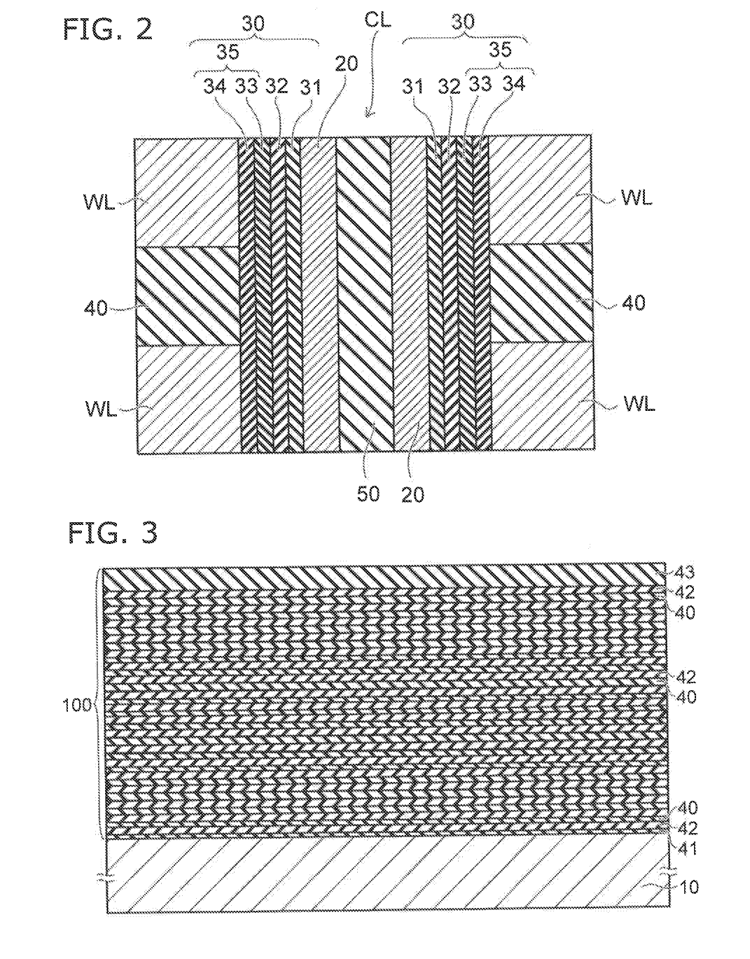

A source side select gate (a lower gate layer) SGS is provided on the substrate 10 via an insulating layer. On the source side select gate SGS, a stacked body 15 formed by alternately stacking electrode layers WL and insulating layers respectively one by one is provided. As shown in FIG. 2, an insulating layer 40 is provided between the electrode layer WL and the electrode layer WL. Drain side select gates (upper gate layers) SGD are provided on the top electrode layer WL via an insulating layer.

The source side select gate SGS, the drain side select gates SGD, and the electrode layers WL are metal layers (e.g., layers mainly containing tungsten). Alternatively, the source side select gate SGS, the drain side select gates SGD, and the electrode layers WL are silicon layers containing silicon as a main component. For example, boron is doped in the silicon layers as impurities for imparting electric conductivity. Alternatively, the source side select gate SGS, the drain side select gates SGD, and the electrode layers WL may contain a metal silicide.

A plurality of bit lines BL (metal films) are provided on the drain side select gates SGD via insulating layers.

The drain side select gates SGD are separated into a plurality of the drain side select gates SGD to correspond to rows of a plurality of columnar sections CL arrayed in the X-direction. Each of the drain side select gates SGD extends in the X-direction. The bit lines BL are separated into a plurality of the bit lines BL in the X-direction to correspond to rows of the plurality of columnar sections CL arrayed in the Y-direction. Each of the bit lines BL extends in the Y-direction.

A plurality of the columnar sections CL pierce through a stacked body 100 including the source side select gate SGS, a stacked body 15 including the plurality of electrode layers WL, and the drain side select gates SGD. The columnar sections CL extend in a stacking direction (Z-direction) of the stacked body 15. The columnar sections CL are formed in, for example, a columnar shape or an elliptical columnar shape. The stacked body 100 is separated into a plurality of blocks in the Y-direction. For example, a source layer SL is provided in a separating section of the stacked body 100.

The source layer SL contains metal (e.g., tungsten). The lower end of the source layer SL is connected to the substrate 10. The upper end of the source layer SL is connected to a not-shown upper layer interconnect. An insulating film is provided between the source layer SL and the electrode layers WL, between the source layer SL and the source side select gate SGS, and between the source layer SL and the drain side select gates SGD.

FIG. 2 is an enlarged schematic sectional view of a part of the columnar section CL.

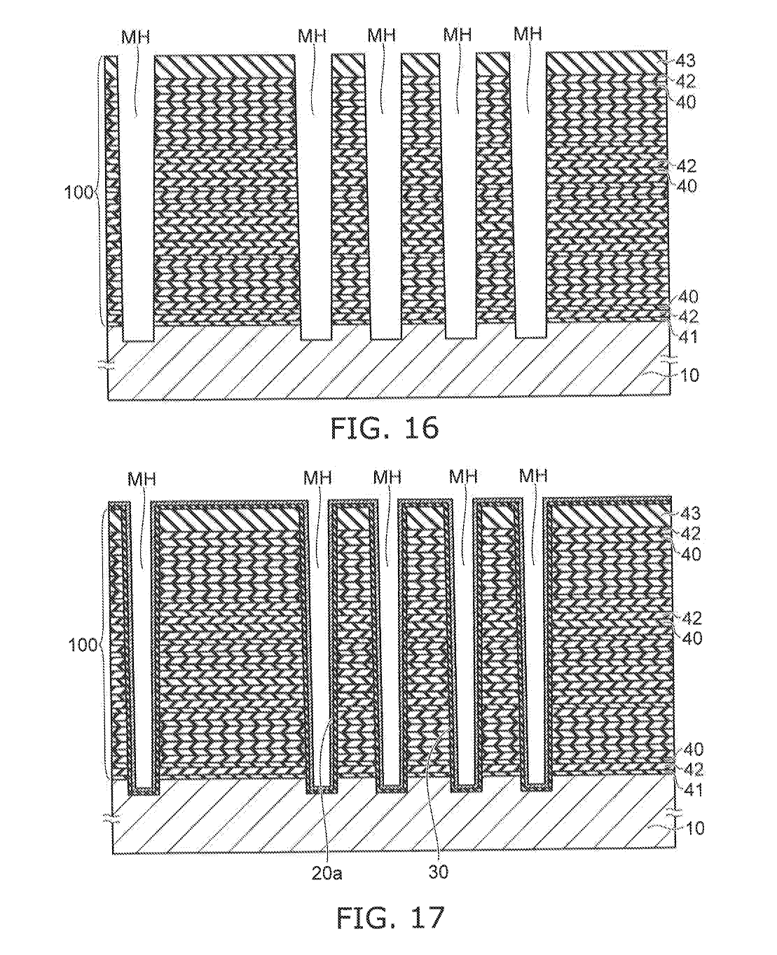

The columnar section CL is formed in a memory hole MH (shown in FIG. 16) formed in the stacked body 100. A channel film 20 is provided in the memory hole MH. The channel film 20 is a silicon film containing, for example, silicon as a main component. The channel film 20 substantially does not include impurities.

The channel film 20 is formed in a cylindrical shape extending in a stacking direction of the stacked body 100. The upper end portion of the channel film 20 pierces through the drain side select gate SGD and is connected to the bit line BL shown in FIG. 1. The lower end portion of the channel film 20 pierces through the source side select gate SGS and is connected to the substrate 10. The lower end of the channel film 20 is electrically connected to the source layer SL via the substrate 10.

As shown in FIG. 2, a memory film 30 is provided between the sidewall of the memory hole and the channel film 20. The memory film 30 includes a block insulating film 35, a charge storage film 32, and a tunnel insulating film 31. The memory film 30 is formed in a cylindrical shape extending in the stacking direction of the stacked body 100.

The block insulating film 35, the charge storage film 32, and the tunnel insulating film 31 are provided in order from the electrode layer WL side between the electrode layers WL and the channel film 20. The block insulating film 35 is in contact with the electrode layers WL. The tunnel insulating film 31 is in contact with the channel film 20. The charge storage film 32 is provided between the block insulating film 35 and the tunnel insulating film 31.

The memory film 30 surrounds the channel film 20. The electrode layers WL surround the outer circumference of the channel film 20 via the memory film 30. A core insulating film 50 is provided on the inner side of the channel film 20.

The electrode layers WL function as control gates of the memory cells. The charge storage film 32 functions as a data storage layer that stores charges injected from the channel film 20. Memory cells having a vertical transistor structure in which the control gates surround the channel film 20 are formed in crossing portions of the channel film 20 and the electrode layers WL.

The semiconductor memory device of the embodiment is a nonvolatile semiconductor memory device that can electrically freely perform erasing and writing of data and can retain stored contents even if a power supply is turned off.

The memory cells are, for example, memory cells of a charge trap type. The charge storage film 32 includes a large number of trap sites that capture charges and includes, for example, a silicon nitride film.

The tunnel insulating film 31 functions as a potential barrier when charges are injected into the charge storage film 32 from the channel film 20 or when the charges stored in the charge storage film 32 diffuse to the channel film 20. The tunnel insulating film 31 includes, for example, a silicon oxide film. As the tunnel insulating film 31, a stacked film (an ONO film) having structure in which a silicon nitride film is sandwiched by a pair of silicon oxide films may be used. When the ONO film is used as the tunnel insulating film 31, an erasing operation can be performed with a low electric field compared with a single layer of a silicon oxide film.

The block insulating film 35 prevents the charges stored in the charge storage film 32 from diffusing to the electrode layers WL. The block insulating film 35 includes a cap film 34 provided in contact with the electrode layers WL and a block film 33 provided between the cap film 34 and the charge storage film 32.

The block film 33 is, for example, a silicon oxide film. The cap film 34 is a film having a dielectric constant higher than the dielectric constant of the silicon oxide film. The cap film 34 is, for example, a silicon nitride film, an aluminum oxide film, a hafnium oxide film, or an yttrium oxide film. By providing such a cap film 34 in contact with the electrode layers WL, it is possible to suppress back tunnel electrons injected from the electrode layers WL during erasing.

As shown in FIG. 1, a drain side select transistor STD is provided in the upper end portion of the columnar section CL. A source side select transistor STS is provided on the lower end portion of the columnar section CL.

The memory cells, the drain side select transistor STD, and the source side select transistor STS are vertical transistors in which an electric current flows in the stacking direction (Z-direction) of the stacked body 100.

The drain side select gates SGD function as gate electrodes (control gates) of the drain side select transistor STD. An insulating film functioning as a gate insulating film of the drain side select transistor STD is provided between the drain side select gates SGD and the channel film 20.

The source side select gate SGS functions as a gate electrode (a control gate) of the source side select transistor STS. An insulating film functioning as a gate insulating film of the source side select transistor STS is provided between the source side select gate SGS and the channel film 20.

A plurality of memory cells including the electrode layers WL as control gates are provided between the drain side select transistor STD and the source side select transistor STS. The plurality of memory cells, the drain side select transistor STD, and the source side select transistor STS are connected in series through the channel film 20 and configure one memory string MS. A plurality of the memory strings MS are arrayed in the X-direction and the Y-direction, whereby the plurality of memory cells are three-dimensionally provided in the X-direction, the Y-direction, and the Z-direction.

The columnar section CL is formed in the memory hole. The memory hole is formed by, for example, a RIE (Reactive Ion Etching) method using a mask layer formed on the stacked body 100. For an increase in a storage capacity, high-density formation of the memory cells is demanded. For example, the diameter of the memory hole tends to be small and the number of the stacked electrode layers WL tends to increase. The memory hole is a micro hole having an extremely high aspect ratio.

A hole (mask hole) is formed in the mask layer by RIE method. When the aspect ratio of the memory hole increases, the thickness of the mask layer increases and the aspect ratio of the mask hole also increases. In RIE of a hole having a high aspect ratio, when symmetry of arrangement patterns of a plurality holes is low, erosion of the mask layer during RIE asymmetrically occurs. It tends to be difficult to form a hole having high circularity and having uniform size.

FIG. 29 is a schematic sectional view showing the asymmetrical erosion of the mask layer.

For example, a mask layer 44 in a region having a relatively small inter-hole distance tends to retract in a thickness direction relatively quickly as shown in FIG. 29. When such asymmetrical mask erosion occurs, the side surface of the mask hole is easily tapered. When ions 200 recoil in an oblique direction on the taper surface, it is likely that the ions 200 advances side etching of the memory hole MH and deteriorates the shape of the memory hole MH.

Therefore, according to an embodiment described below, there is provided a method that can suppress distortion of the mask hole and, as a result, the shape of the memory hole can be appropriately controlled.

FIGS. 3 to 8B are schematic views showing a method for forming the memory hole of the semiconductor memory device of a first embodiment.

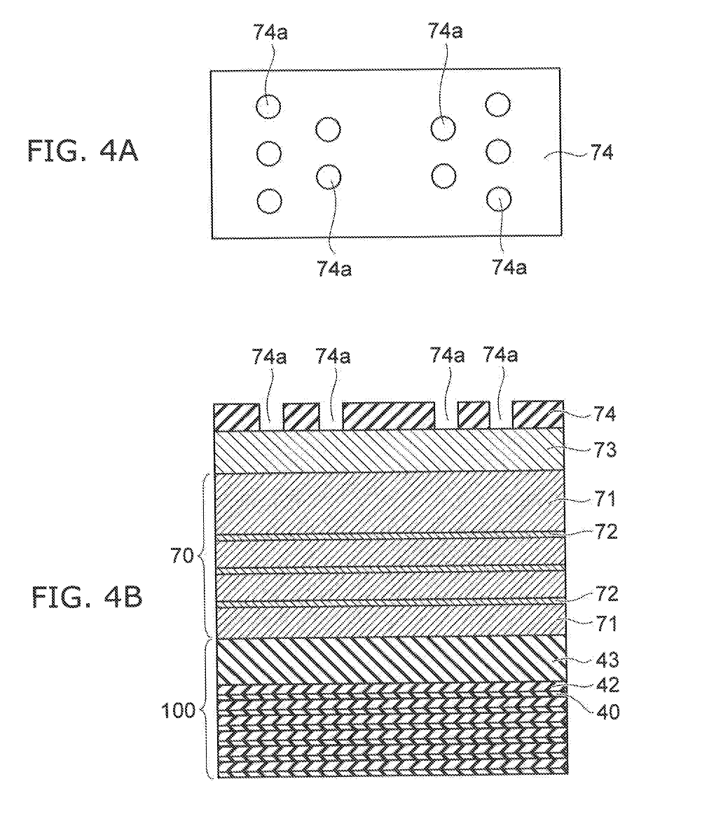

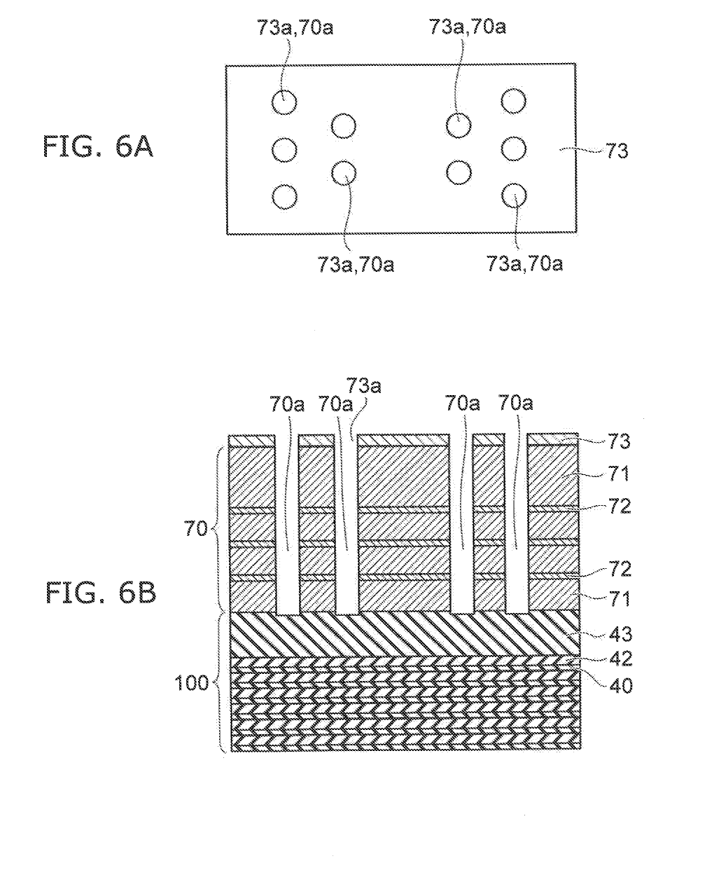

FIGS. 3, 4B, 5A, 5B, 6B, 7A, 7B, 8A, and 8B are sectional views. FIG. 4A is a top view of FIG. 4B. FIG. 6A is a top view of FIG. 6B.

As shown in FIG. 3, an etching target layer (a foundation layer) 100 is formed on the substrate 10. The etching target layer 100 is a stacked body including, between an insulating layer 41 and an insulating layer 43, a plurality of sacrificial layers (fourth layers) 42 and a plurality of insulating layers (fifth layers) 40. The substrate 10 is, for example, a semiconductor substrate and is a silicon substrate.

The insulating layer 41 is formed on the substrate 10. The insulating layer 41 is a silicon oxide layer containing, for example, silicon oxide as a main component.

The sacrificial layers 42 and the insulating layers 40 are alternately formed on the insulating layer 41. A process for alternately forming the sacrificial layers 42 and the insulating layers 40 is repeated a plurality of times. The number of stacked layers of the sacrificial layer 42 and the insulating layer 40 is not limited to the number of layers shown in the figure.

The insulating layers 40 are silicon oxide layers containing, for example, silicon oxide as a main component. The sacrificial layers 42 are layers formed of a material different from the material of the insulating layers 40. For example, the sacrificial layers 42 are silicon nitride layer containing, silicon nitride as a main component. The sacrificial layers 42 are replaced with the select gates SGS and SGD and the electrode layers WL in a later process.

The insulating layer 43 is formed on the top sacrificial layer 42. The insulating layer 43 is, for example, a silicon oxide layer of the same type as the insulating layers 40 containing silicon oxide as a main component.

As shown in FIG. 4B, a mask layer 70 is formed on the insulating layer 43. The mask layer 70 is formed on the etching target layer 100. The top layer of the etching target layer 100 is not limited to the insulating layer 43.

The mask layer 70 includes a plurality of first layers 71, and one or more second layers 72 respectively provided between adjacent first layers 71. The first layer 71 and the second layer 72 are alternately stacked on the insulting layer 43.

The first layers 71 are formed of a material different from the material of the layers forming the etching target layer 100. For example, the first layers 71 are carbon layers containing carbon as a main component.

The second layers 72 are layers formed of a material different from the material of the first layers 71. For example, the second layers 72 are silicon oxide layers containing silicon oxide as a main component. The second layers 72 may be silicon layers containing silicon as a main component.

A third layer 73 is formed on the top first layer 71. The third layer 73 is a layer formed of the same material as the material of the second layers 72. For example, the third layer 73 is a silicon oxide layer containing silicon oxide as a main component. The thickness of the third layer 73 is thicker than the total thickness of the plurality of second layers 72.

The carbon layers (the first layers 71) and the silicon oxide layers (the second layers 72 and the third layer 73) are formed by, for example, a CVD (Chemical Vapor Deposition) method. The carbon layers and the silicon oxide layers are continuously alternately formed by switching source gases in the same chamber. That is, in forming a stacked film of the first layers 71, the second layers 72, and the third layer 73, films of two types of materials only have to be formed. Therefore, condition setting and the like can be easily performed.

A resist film 74 is formed on the third layer 73. As shown in FIG. 4B, a plurality of openings (holes) 74a are formed by a lithography method in the resist film 74. The openings 74a reach the third layer 73. In a memory cell array region, as shown in FIG. 4A, there are a first region where the plurality of openings 74a are relatively densely disposed and a second region where the plurality of openings 74a are relatively sparsely disposed.

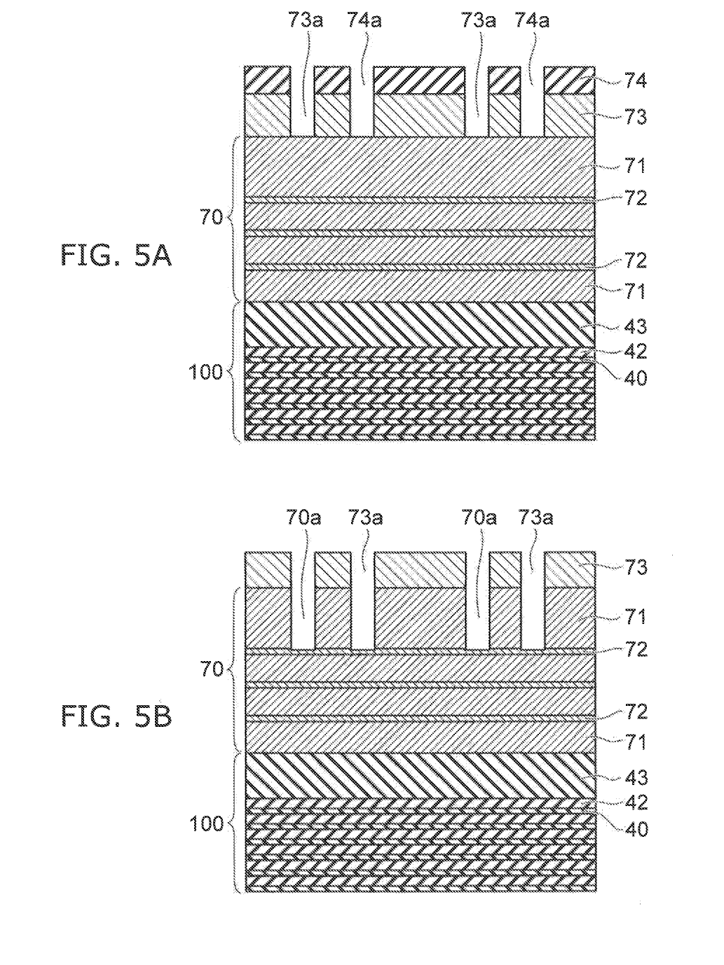

As shown in FIG. 5A, holes 73a are formed in the third layer 73 by RIE method using the resist film 74 as a mask. The holes 73a reach the top first layer 71.

Further, as shown in FIG. 5B, mask holes 70a are formed in the top first layer 71 by RIE method using the resist film 74 and the third layer 73 as a mask. During the etching, the resist film 74 disappears. The mask holes 70a pierce through the top first layer 71 and reach the top second layer 72. The second layer 72 has etching resistance higher than the etching resistance of the first layer 71 with respect to an etching condition in this case. The second layer 72 functions as an etching stopper.

Subsequently, the etching of the mask layer 70 is continued by RIE method using the third layer 73 as a mask. As shown in FIG. 6B, a plurality of mask holes 70a are formed in the mask layer 70. The mask holes 70a pierce through the mask layer 70 and reach the top layer (the insulating layer 43) of the etching target layer 100.

In the memory cell array region, as shown in FIG. 6A, there are a first region where the plurality of mask holes 70a are relatively densely disposed and a second region where the plurality of mask holes 70a are relatively sparsely disposed.

In this etching, an etching selectivity of the first layers 71 is higher than an etching selectivity of the third layer 73. The second layers 72 formed of the same material as the material of the third layer 73 are etched unselectively together with the third layer 73. Therefore, when the second layers 72 are etched, the third layer 73 also retracts. However, since the thickness of the third layer 73 is thicker than the total thickness of the second layers 72, the third layer 73 does not disappear before the etching of the mask layer 70 ends.

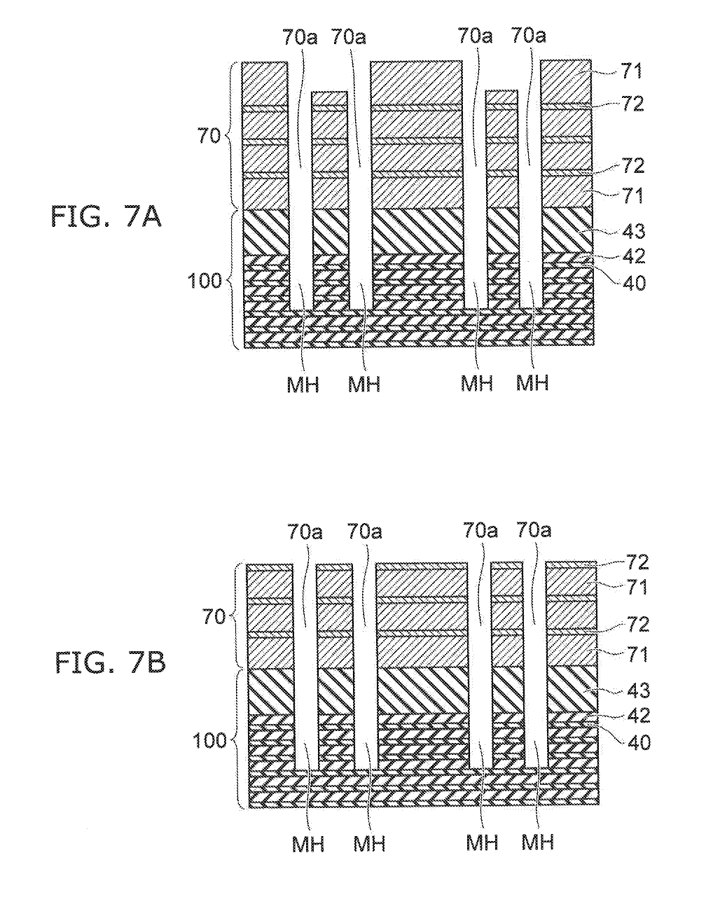

Subsequently, the etching target layer 100 is etched by RIE method using the mask layer 70 as a mask. As shown in FIG. 7A, the etching target layer 100 under the mask holes 70a is etched. Memory holes MH are formed in the etching target layer 100.

The etching target layer 100 does not include a layer formed of the same material as the material of the first layers 71. The etching selectivity of the etching target layer 100 is higher than the etching selectivity of the first layers 71. Therefore, the first layers 71 function as substantial masks in the mask layer 70 when the etching target layer 100 is etched. The thickness of the respective first layers 71 is thicker than the thickness of the respective second layers 72. An etching rate of the first layers 71 is, for example, not more than one tenth of an etching rate of the etching target layer 100.

The silicon oxide layers (the insulating layer 43 and the insulating layers 40) and the silicon nitride layers (the sacrificial layers 42) are nonselectively continuously etched using the same first gas (e.g., gas containing fluorocarbon or hydrofluorocarbon).

The third layer 73, which is the silicon oxide layer, is also etched and disappears. According to the disappearance of the third layer 73, the first layer 71 formed directly under the third layer 73 is exposed to the outermost layer of the mask layer 70.

During the etching for forming the memory holes MH, the first layers 71 are also etched at an etching rate sufficiently lower than the etching rate of the etching target layer 100. In particular, in etching at a low rate, retraction speed of the mask layer 70 fluctuates depending on the distance between the holes 70a adjacent to each other. As shown in FIG. 7A, fluctuation (in-plane fluctuation) tends to occur in the upper surface height of the mask layer 70.

For example, depending on a condition, in a region where the distance between the holes 70a is small, there is a tendency that the mask layer 70 retracts fast and the upper surface height decreases compared with a region where the distance between the holes 70a is large. As the depth of the memory holes MH increase and an etching time increase, a difference in the upper surface height of the mask layer 70 becomes conspicuous. As described above with reference to FIG. 29, the fluctuation in the upper surface height of the mask layer 70 causes deterioration in shape controllability of the memory holes MH.

Therefore, according to the first embodiment, while the etching of the etching target layer 100 is performed using the first gas, when fluctuation occurs in the upper surface height of the first layer 71 exposed to the outermost most layer of the mask layer 70, gas introduced into a chamber is switched from the first gas to a second gas. The first layers 71 are etched under a condition in which the etching selectivity of the first layers 71 is higher than the etching selectivity of the second layers 72.

For example, timing for switching the first gas to the second gas is controlled using time parameter. The first gas is switched to the second gas before the outermost first layer 71 disappears and the second layer 72 under the first layer 71 appears.

The second gas contains, for example, at least any one of oxygen (O₂), hydrogen (H₂), and ammonium (NH₃). The outermost first layer 71 is etched back and removed by RIE method using the second gas. As shown in FIG. 7B, the second layer 72 formed directly under the outermost first layer 71 is exposed by the removal of the outermost first layer 71.

The second layer 72 has etching resistance higher than the etching resistance of the first layer 71 with respect to the etching condition in which the second gas is used. The second layer 72 functions as an etching stopper. An etching rate of the second layers 72 is, for example, not more than one tenth of an etching rate of the first layers 71. In this etching, bias power applied to the substrate 10 side is increased to anisotropically etch the outermost first layer 71 such that the other first layers 71 present under the outermost first layer 71 are not isotropically etched.

The first layers 71 are not limited to the carbon layers and may be silicon layers containing silicon as a main component. For example, the second layers 72 of the silicon oxide layers can be combined with the first layers 71 of the silicon layers. For example, gas containing hydrogen bromide (HBr) can be used as the second gas for the combination of the first layers (silicon layers) 71 and the second layers (silicon oxide layers) 72.

By etching and removing the outermost first layer 71 using the second layer 72 as a stopper, as shown in FIG. 7B, the upper surface height of the mask layer 70 is uniformly aligned with the height of the second layer 72.

Subsequently, the gas introduced into the chamber is switched from the second gas to the first gas and the etching for forming the memory holes MH in the etching target layer 100 is resumed. The second layer 72 having the same material as the material of the insulating layer 40 of the etching target layer 100 disappears during the etching using the first gas. According to the disappearance of the second layer 72 exposed to the outermost layer of the mask layer 70, the first layer 71 is exposed to the outermost layer of the mask layer 70. The etching of the etching target layer 100 is advanced using the first layer 71 as a substantial mask.

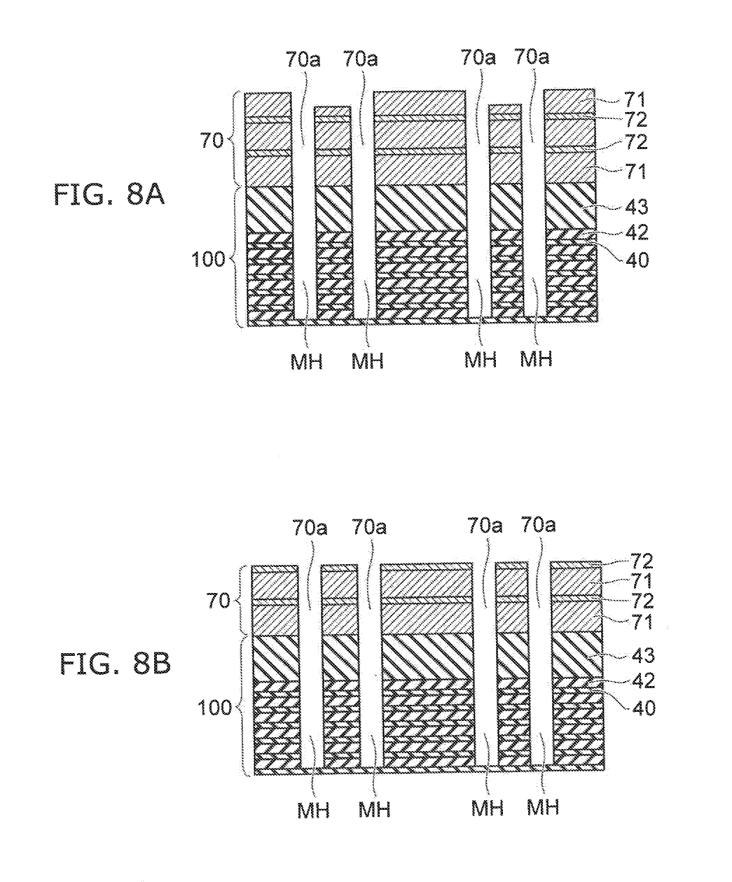

According to the progress of the etching, as shown in FIG. 8A, when fluctuation occurs in the upper surface height of the outermost first layer 71, the gas introduced into the chamber is switched from the first gas to the second gas and the outermost first layer 71 is etched under a condition in which the etching selectivity of the outermost first layer 71 is higher than the etching selectivity of the second layers 72.

The outermost first layer 71 is etched back and removed by RIE method using the second gas. According to the removal of the outermost first layer 71, as shown in FIG. 8B, the second layer 72 formed directly under the outermost first layer 71 is exposed.

In this case, as in the case described above, bias power applied to the substrate 10 side is increased to anisotropically etch the outermost first layer 71 such that the other first layers 71 present under the outermost first layer 71 are not isotropically etched.

By etching and removing the outermost first layer 71 using the second layer 72 as a stopper, as shown in FIG. 8B, the upper surface height of the mask layer 70 can be uniformly aligned with the height of the second layer 72.

The etching of the etching target layer 100 using the first gas and the etching of the outermost first layer 71 using the second gas described above are repeated a plurality of times to form the memory holes MH in the etching target layer 100 as shown in FIG. 16. The memory holes MH reach the substrate 10. The number of the first layers 71 and the total thickness of the plurality of first layers 71 are set such that at least one first layer 71 remains until the formation of the memory holes MH ends.

The etching of the etching target layer 100 using the first gas and the etching of the outermost first layer 71 using the second gas are continuously performed, for example, while the gas introduced into the same chamber is switched.

According to the first embodiment, even if asymmetrical erosion of the mask layer 70 (the first layers 71) shown in FIGS. 7A and 8A occurs, the outermost first layer 71 in which the asymmetrical erosion occurs is removed using the second layer 72 as a stopper. Therefore, it is possible to advance the etching of the etching target layer 100 while cancelling the asymmetrical erosion of the mask layer 70.

As a result, it is possible to suppress side etching of the memory holes MH due to recoil ions. Therefore, it is possible to advance etching in substantially the vertical direction with respect to the major surface of the substrate 10. As a result, it is easy to form the memory holes MH having straight sidewalls with diameter fluctuation in the depth direction suppressed. The memory holes MH having a proper shape can suppress, for example, fluctuation in memory cell characteristics in the stacking direction.

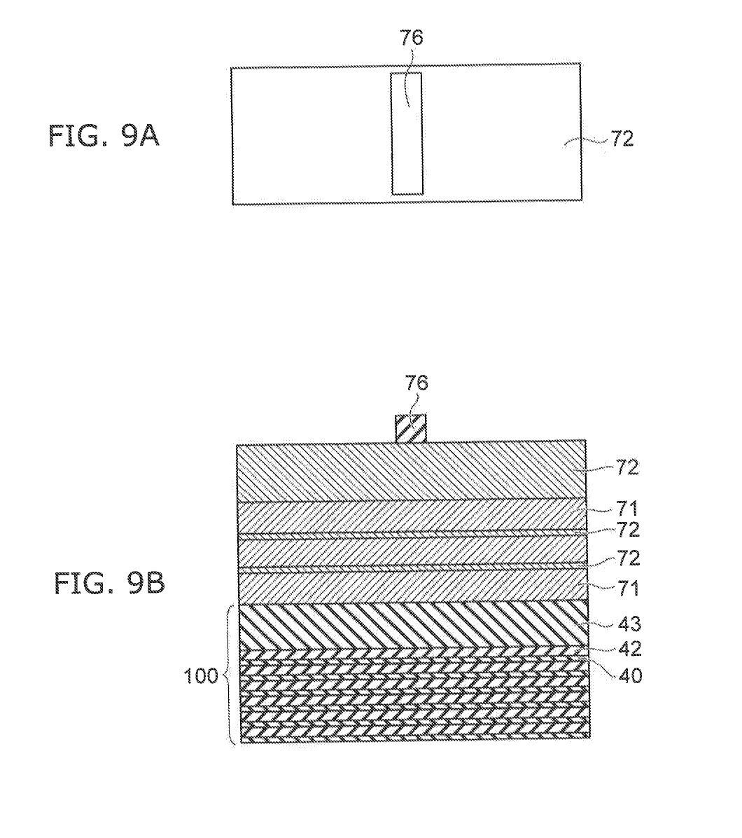

FIGS. 9A to 158 are schematic views showing a method for forming a memory hole of a semiconductor memory device of a second embodiment.

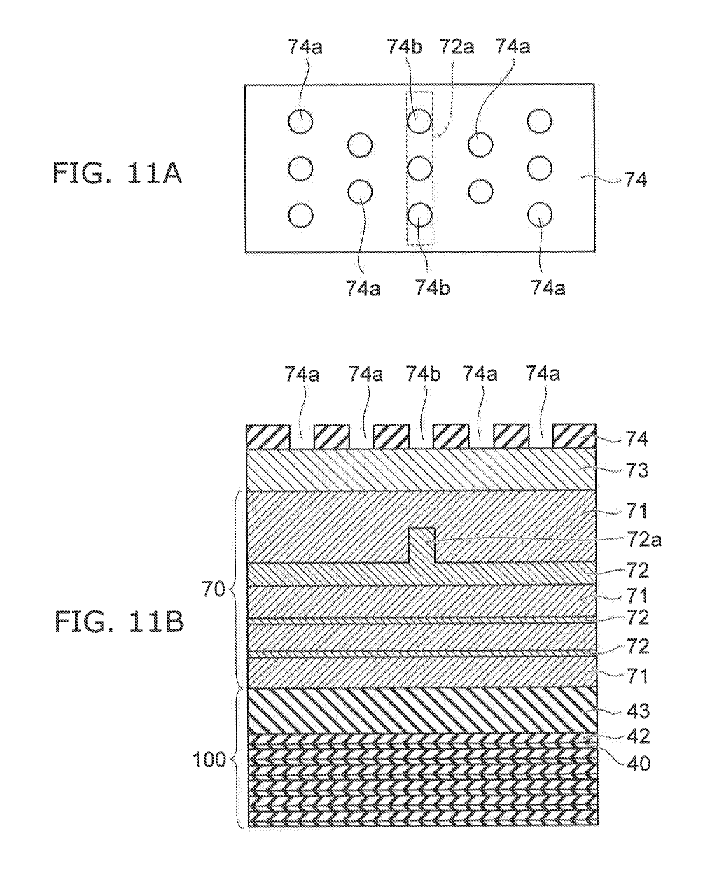

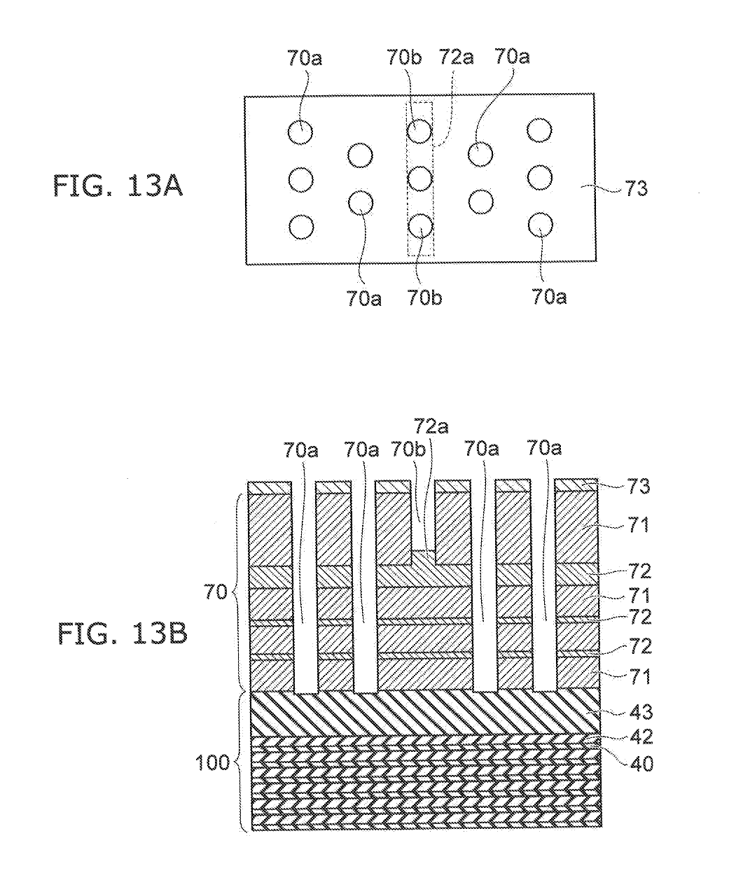

FIGS. 9B, 10A, 10B, 11B, 12, 138, 14A, 14B, 15A, and 158 are sectional views. FIG. 9A is a top view of FIG. 9B. FIG. 11A is a top view of FIG. 11B. FIG. 13A is a top view of FIG. 13B.

As shown in FIG. 9B, the first layers 71 and the second layers 72 are alternately stacked on the top layer (the insulating layer 43) of the etching target layer 100. The material of the first layers 71 and the material of the second layers 72 are the same as the material in the first embodiment.

A projected section is processed in the top second layer 72 by half etching in the thickness direction as described below. The top second layer 72 is formed thicker than the other second layers 72 under the top second layer 72.

A resist film 76 is formed on the top second layer 72. The resist film 76 is linearly patterned by lithography method as shown in FIG. 9A.

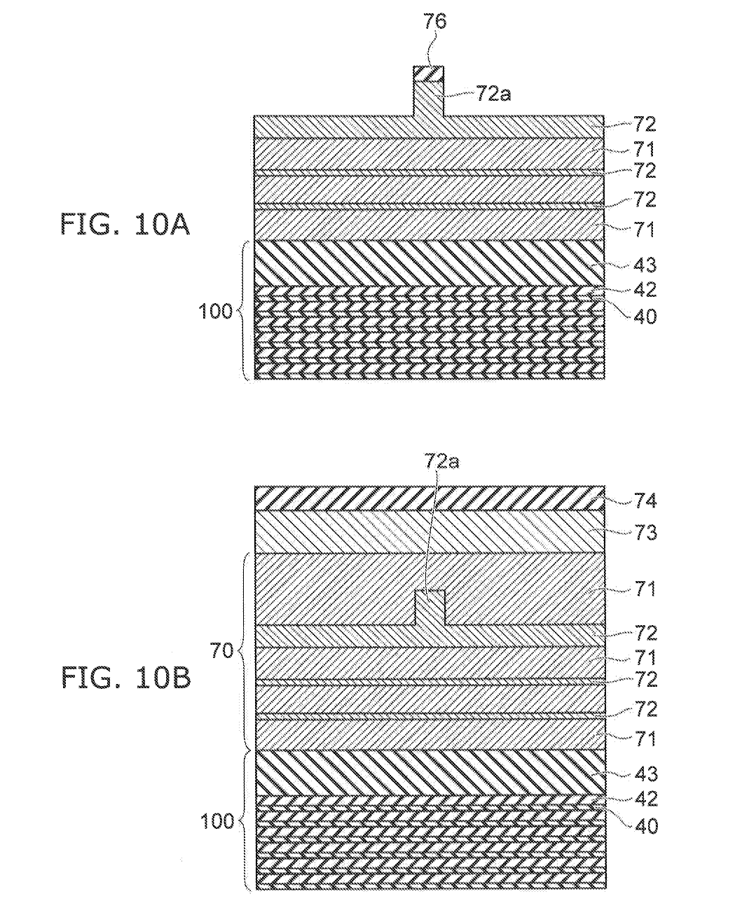

The top second layer 72 is etched by RIE method using the resist film 76 as a mask. As shown in FIG. 10A, the etching of the second layer 72 is stopped halfway in the thickness direction. A projected section 72a of the second layer 72 is left under the resist film 76.

After the resist film 76 is removed, as shown in FIG. 108, the first layer 71 is formed on the top second layer 72. The first layer 71 is the top layer of the mask layer 70. The top first layer 71 covers the projected section 72a of the second layer 72.

The mask layer 70 including the plurality of first layers 71 and the plurality of second layers 72 is formed on the etching target layer 100, The second layer 72 is provided between the first layers 71. The projected section 72a is formed in a part of the top second layer 72 among the plurality of second layers 72.

The third layer 73 is formed on the top first layer 71. As in the first embodiment, the third layer 73 is a layer formed of the same material as the material of the second layer 72 and is, for example, a silicon oxide layer. The thickness of the third layer 73 is thicker than the total thickness of the plurality of second layers 72 excluding the projected section 72a.

The resist film 74 is formed on the third layer 73. In the resist film 74, the plurality of first openings (holes) 74a and a plurality of second openings (holes) 74b are formed by lithography method, as shown in FIG. 11B. The first openings 74a and the second openings 74b reach the third layer 73.

As shown in FIG. 11A, the second openings 74b are formed above the projected section 72a of the second layer 72. The plurality of second openings 74b are arrayed spaced apart in the longitudinal direction of the projected section 72a formed in the linear pattern shape. The diameter of the second opening 74b and the width of the projected section 72a are substantially the same.

As shown in FIG. 11A, the plurality of first openings 74a and the plurality of second openings 74b are cyclically arrayed in a pattern having high symmetry, for example, a hexagonal close-packed pattern.

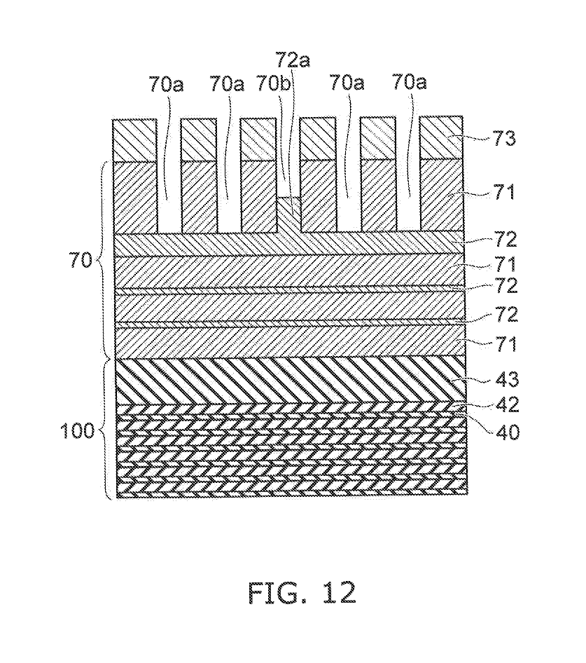

As shown in FIG. 12, holes are formed in the third layer 73 by RIE method using the resist film 74 as a mask. Further, first mask holes 70a and second mask holes 70b are formed in the top first layer 71 by RIE method using the resist film 74 and the third layer 73 as a mask. During the etching, the resist film 74 disappears. The second layer 72 has etching resistance higher than the etching resistance of the first layer 71 with respect to an etching condition in this case. The second layer 72 functions as an etching stopper.

The first mask holes 70a pierce through the top first layer 71 and reach a region where the projected section 72a is absent in the top second layer 72. The second mask holes 70b pierce through the first layer 71 on the projected section 72a of the top second layer 72 and reach the projected section 72a. Therefore, the second mask holes 70b are shallower than the first mask holes 70a.

Subsequently, the etching of the mask layer 70 is continued by RIE method using the third layer 73 as a mask. As shown in FIGS. 13A and 13B, the plurality of first mask holes 70a and the plurality of second mask holes 70b are formed in the mask layer 70.

The etching selectivity of the first layers 71 is higher than the etching selectivity of the third layer 73. The second layers 72 having the same material as the material of the third layer 73 are etched unselectively together with the third layer 73. Therefore, when the second layers 72 are etched, the third layer 73 also retracts. However, since the thickness of the third layer 73 is thicker than the total thickness of the plurality of second layers 72, the third layer 73 does not disappear before the etching of the mask layer 70 ends.

The projected section 72a of the second layer 72 also retracts. However, initial height in FIG. 10A is set such that the projected section 72a remains after the etching of the mask layer 70 ends.

The first mask holes 70a pierce through the mask layer 70 and reach the top insulating layer 43 of the etching target layer 100. In a state in which the first mask holes 70a pierce through the mask layer 70, the projected section 72a of the second layer 72 remains under the second mask holes 70b. Therefore, the second mask holes 70b are shallower than the first mask holes 70a.

As shown in FIG. 13A, the plurality of first mask holes 70a and the plurality of second mask holes 70b are cyclically arrayed in a pattern having high symmetry, for example, a hexagonal close-packed pattern.

The plurality of second mask holes 70b are arrayed spaced apart in the longitudinal direction of the projected section 72a formed in the linear pattern shape. The diameter of the second mask holes 70b and the width of the projected section 72a are substantially the same.

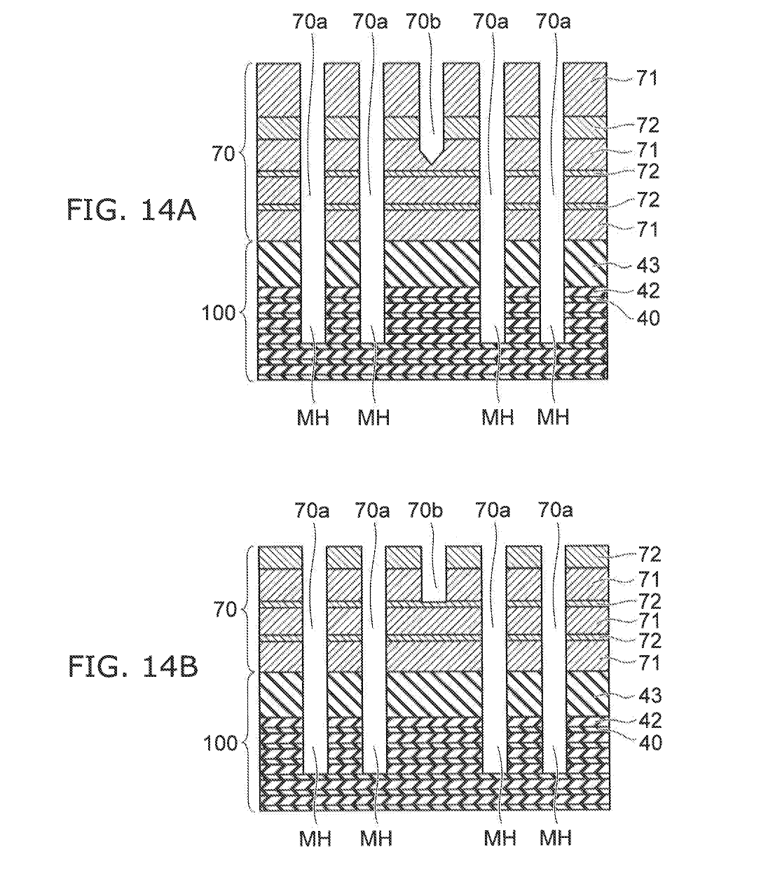

Subsequently, the etching target layer 100 is etched by RIE method using the mask layer 70 as a mask. As shown in FIG. 14A, the etching target layer 100 under the first mask holes 70a is etched. The memory holes MH are formed in the etching target layer 100.

The etching target layer 100 does not include a layer formed of the same material as the material of the first layers 71. The etching selectivity of the etching target layer 100 is higher than the etching selectivity of the first layers 71. The first layers 71 function as substantial masks in the mask layer 70 when the etching target layer 100 is etched. The thickness of the respective first layers 71 is thicker than the thickness of the respective second layers 72. An etching rate of the first layers 71 is, for example, not more than one tenth of an etching rate of the etching target layer 100.

The silicon oxide layers (the insulating layer 43 and the insulating layers 40) and the silicon nitride layers (the sacrificial layers 42) are nonselectively continuously etched using the same first gas (e.g., gas containing fluorocarbon or hydrofluorocarbon).

The third layer 73, which is the silicon oxide layer, is also etched and disappears. According to the disappearance of the third layer 73, the first layer 71 formed directly under the third layer 73 is exposed to the outermost layer of the mask layer 70.

The plurality of first mask holes 70a and the plurality of second mask holes 70b are cyclically arrayed in a pattern having high symmetry, for example, a hexagonal close-packed pattern. The first layer 71 exposed to the outermost layer of the mask layer 70 uniformly retracts. Fluctuation less easily occurs in the upper surface height of the mask layer 70.

The second layer 72 is a layer formed of the same material as the material of the silicon oxide layers (the insulating layers 43 and 40) of the etching target layer 100. Therefore, when the etching target layer 100 is etched using the first gas, the projected section 72a under the second mask holes 70b and the top second layer 72 under the projected section 72a are also etched. As shown in FIG. 14A, the second mask holes 70b reach the first layer 71 (the first layer 71 second from the top) directly under the top second layer 72.

When the etching is performed using the first gas, the first layers 71 are also etched, although the etching rate is sufficiently lower than the etching rate of the etching target layer 100. In the etching at the low rate, it is difficult to control a hole shape. For example, as shown in FIG. 14A, the bottoms of the second mask holes 70b reaching the first layer 71 tend to have a taper shape. In portions where tapers are formed, a hole diameter decreases. An interval between the second mask holes 70b and the first mask holes 70a adjacent to the second mask holes 70b changes.

As described above, the change in the hole interval causes fluctuation in retraction speed of the mask layer 70 (the upper surface height of the mask layer 70), that is, occurrence of asymmetrical erosion of the mask layer 70.

Therefore, according to the second embodiment, while the etching target layer 100 is etched using the first gas, when the second mask holes 70b reach the first layer 71 under the outermost first layer 71, the gas introduced into the chamber is switched from the first gas to the second gas. The etching selectivity of the first layers 71 is higher than the etching selectivity of the second layers 72. For example, timing for switching the first gas to the second gas is controlled using time parameter.

As in the first embodiment, the second gas contains, for example, at least any one of oxygen (O₂), hydrogen (H₂), and ammonium (NH₃). The first layer 71 directly under the second mask holes 70b is removed by RIE method using the second gas. As shown in FIG. 14B, the second mask holes 70b reach the second layer 72 (the second layer 72 second from the top) under the top second layer 72. By etching the first layers 71 at the etching selectivity sufficiently higher than the etching selectivity of the second layers 72 using the second gas, it is possible to eliminate the taper shape of the bottoms of the second mask holes 70b.

When the etching is performed using the second gas, the outermost first layer 71 is also etched back and removed. According to the removal of the outermost first layer 71, as shown in FIG. 14B, the second layer 72 formed directly under the removed outermost first layer 71 is exposed to the outermost layer of the mask layer 70.

The second layer 72 has etching resistance higher than the etching resistance of the first layer 71 with respect to the etching condition in which the second gas is used. The second layer 72 functions as an etching stopper. An etching rate of the second layer 72 is, for example, not more than one tenth of an etching rate of the first layer 71. In this etching, bias power applied to the substrate 10 side is increased to anisotropically etch the outermost first layer 71 such that the other first layers 71 present under the outermost first layer 71 are not isotropically etched.

In the second embodiment, as in the first embodiment, the first layers 71 are not limited to the carbon layers and may be silicon layers containing silicon as a main component. For example, the second layers 72 of the silicon oxide layers can be combined with the first layers 71 of the silicon layers. For example, gas containing hydrogen bromide (HBr) can be used as the second gas for the combination of the first layers (silicon layers) 71 and the second layers (silicon oxide layers) 72.

Subsequently, the gas introduced into the chamber is switched from the second gas to the first gas and the etching for forming the memory holes MH in the etching target layer 100 is resumed. The second layer 72 of the same type as the insulating layer 40 of the etching target layer 100 disappears during the etching performed using the first gas. According to the disappearance of the second layer 72 exposed to the outermost layer of the mask layer 70, the first layer 71 is exposed to the outermost layer of the mask layer 70. The etching of the etching target layer 100 is advanced using the first layer 71 as a substantial mask.

In this case, as in the case described above, the plurality of first mask holes 70a and the plurality of second mask holes 70b are cyclically arrayed in a pattern having high symmetry, for example, a hexagonal close-packed pattern. Therefore, the first layer 71 exposed to the outermost layer of the mask layer 70 uniformly retracts. Fluctuation less easily occurs in the upper surface height of the mask layer 70.

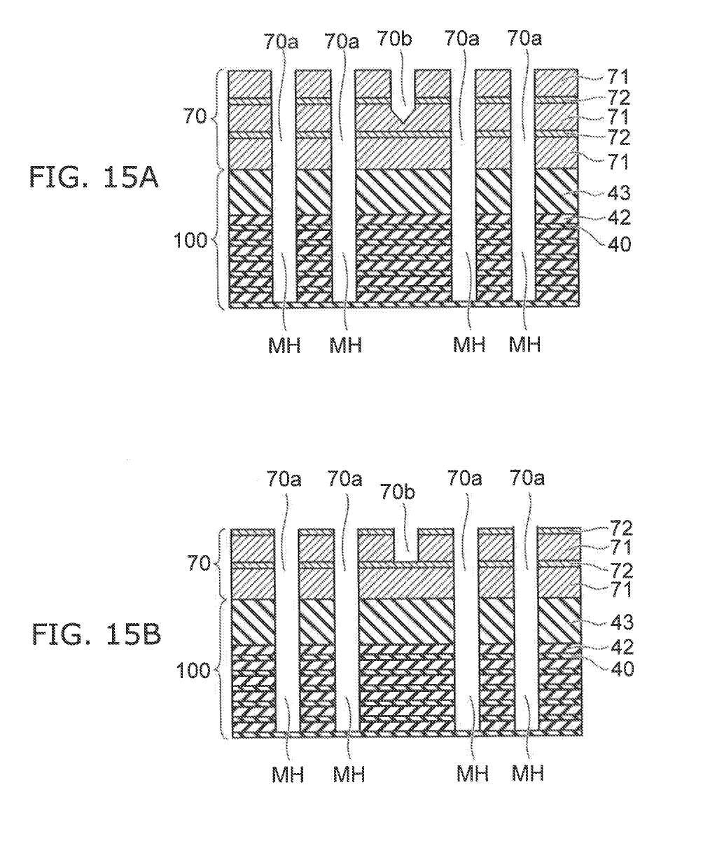

According to the progress of the etching, as shown in FIG. 15A, when the second mask holes 70b pierce through the top second layer 72, reaches the first layer 71 right under the second layer 72, and the bottoms of the second mask holes 70b are formed in a taper shape, the gas introduced into the chamber is switched from the first gas to the second gas and the first layer 71 right under the second mask holes 70b and the outermost first layer 71 are etched under a condition in which the etching selectivity of the outermost first layer 71 is higher than the etching selectivity of the second layers 72.

The first layer 71 directly under the second mask holes 70b is removed by RIE method using the second gas. As shown in FIG. 15B, the second mask holes 70b reach the second layer 72 (the second layer 72 second from the top) under the top second layer 72. By etching the first layers 71 at the etching selectivity sufficiently higher than the etching selectivity of the second layers 72 using the second gas, it is possible to eliminate the taper shape of the bottoms of the second mask holes 70b.

When the etching is performed using the second gas, the outermost first layer 71 is also etched back and removed. According to the removal of the outermost first layer 71, as shown in FIG. 15B, the second layer 72 formed directly under the removed outermost first layer 71 is exposed to the outermost layer of the mask layer 70.

In this etching, bias power applied to the substrate 10 side is increased to anisotropicaliy etch the outermost first layer 71 such that the other first layers 71 present under the outermost first layer 71 are not isotropically etched.

The etching of the etching target layer 100 using the first gas and the etching of the first layer 71 directly under the second mask holes 70b and the outermost first layer 71 using the second gas described above are repeated a plurality of times to form the memory holes MH in the etching target layer 100 as shown in FIG. 16. The memory holes MH reach the substrate 10. The number of the first layers 71 and the total thickness of the plurality of first layers 71 are set such that at least one first layer 71 remains until the formation of the memory holes MH ends.

The second mask holes 70b do not reach the etching target layer 100 until the formation of the memory holes MH ends. Therefore, in the etching target layer 100, memory holes are not formed in a second region under the second mask holes 70b. The memory holes MH are formed in a first region under the first mask holes 70a.

The etching of the etching target layer 100 using the first gas and the etching of the outermost first layer 71 using the second gas are continuously performed, for example, while the gas introduced into the same chamber is switched.

According to the second embodiment, the plurality of first mask holes 70a and the plurality of second mask holes 70b are cyclically arrayed in a pattern having high symmetry in the mask layer 70. Therefore, it is possible to suppress in-plane fluctuation in the upper surface height of the mask layer 70. Further, even if tapers shown in FIGS. 14A and 15A are formed in the bottoms of the second mask holes 70b, the tapers are removed. Therefore, it is possible to advance the etching of the etching target layer 100 while cancelling asymmetrical erosion of the mask layer 70.

As a result, it is possible to suppress side etching of the memory holes MH due to recoil ions. Therefore, it is possible to advance etching in substantially the vertical direction with respect to the major surface of the substrate 10. As a result, it is easy to form the memory holes MH having straight sidewalls with diameter fluctuation in the depth direction suppressed. The memory holes MH having a proper shape can suppress, for example, fluctuation in memory cell characteristics in the stacking direction.

A process after the formation of the memory holes MH is described with reference to FIGS. 16 to 28.

As shown in FIG. 16, the memory holes MH pierce through the etching target layer 100 and reach the substrate 10.

As shown in FIG. 17, the memory films 30 are formed on the inner walls (the sidewalls and the bottoms) of the memory holes MH. Cover films 20a are formed on the inner sides of the memory films 30.

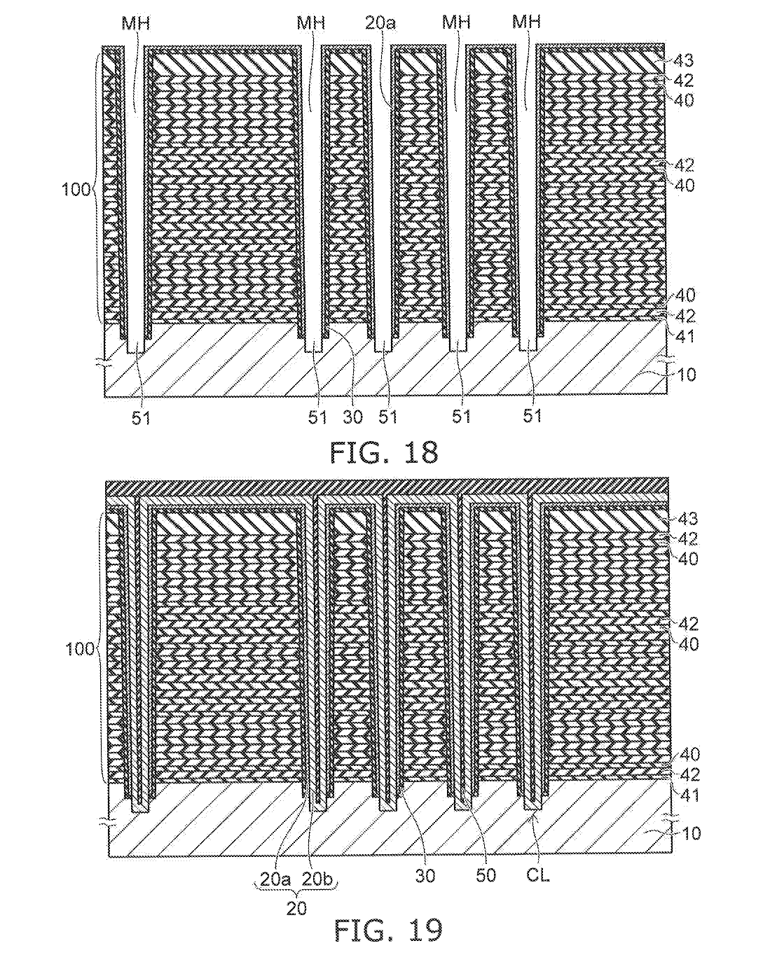

The cover films 20a and the memory films 30 formed in the bottoms of the memory holes MH are removed by RIE method. As shown in FIG. 18, contact holes 51 are formed in the bottoms of the memory holes MH. The substrate 10 forms the side surfaces and the bottom surfaces of the contact holes 51.

When RIE is performed, the memory films 30 formed on the sidewalls of the memory holes MH are covered and protected by the cover films 20a. Therefore, the memory films 30 formed on the sidewalls of the memory holes MH are not damaged by RIE.

Subsequently, as shown in FIG. 19, channel films 20b are formed in the contact holes 51 and on the inner sides of the cover films 20a. After being formed as, for example, amorphous silicon films, the cover films 20a and the channel films 20b are formed as polycrystal silicon films by annealing. The cover films 20a configure a part of the channel films 20 in conjunction with the channel films 20b.

The channel films 20 are electrically connected to the substrate 10 through the channel films 20b formed in the contact holes 51.

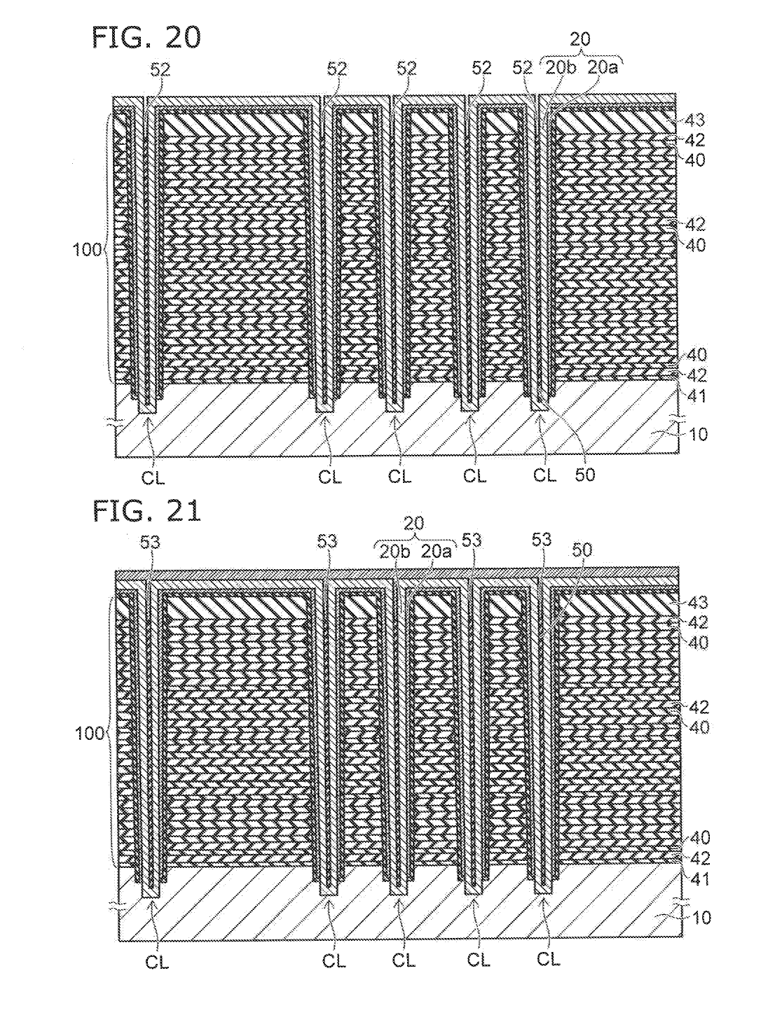

The core insulating films 50 are formed on the inner sides of the channel films 20b. Consequently, the columnar sections CL are formed. Upper parts of the core insulating films 50 are etched back. As shown in FIG. 20, hollows 52 are formed in upper parts of the columnar sections CL.

In the hollows 52, as shown in FIG. 21, semiconductor films are buried. The semiconductor films 53 are, for example, doped silicon films. Impurity concentration of the semiconductor films 53 is higher than impurity concentration of the channel films 20, which are non-doped silicon films.

In a memory of a general charge injection type, substrate potential is increased to extract electrons written in a charge storage layer such as a floating gate and erase data. As another erasing method, there is also a method for boosting channel potential of memory cells making use of a GIDL (Gate Induced Drain Leakage) generated in a channel at the upper end of a drain side select gate.

In the embodiment, holes generated by applying a high electric field to the semiconductor films 53 having the high impurity concentration formed near the upper end portions of the drain side select gates SGD are supplied to the channel films 20 to increase the channel potential. By setting the potential of the electrode layers WL to, for example, ground potential (0 V), electrons in the charge storage film 32 are extracted according to a potential difference between the channel films 20 and the electrode layers WL or holes are injected into the charge storage film 32 and a data erasing operation is performed.

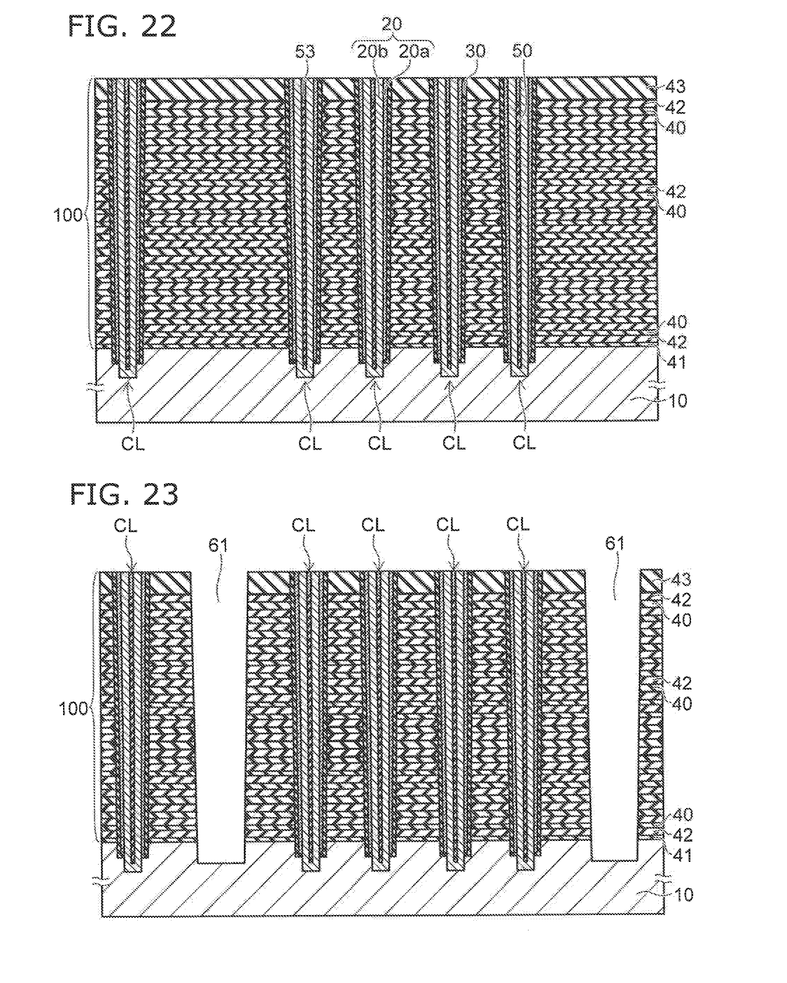

After the semiconductor films 53 are buried in the hollows 52, the memory films 30, the channel films 20, and the semiconductor films 53 deposited on the upper surface of the etching target layer 100 (the upper surface of the insulating layer 43) are removed (FIG. 22).

As shown in FIG. 23, slits 61 are formed in the etching target layer 100 by RIE method using a not-shown mask. The slits 61 pierce through the etching target layer 100 and reach the substrate 10. The second mask holes 70b in the second embodiment are formed on regions where the slits 61 are planned to be formed.

The sacrificial layers 42 are removed by etching through the slits 61. According to the removal of the sacrificial layers 42, as shown in FIG. 24, spaces 62 are formed among the insulating layers 40. The spaces 62 are also formed between the top insulating layer 40 and the insulating layer 43 and between the bottom insulating layer 40 and the insulating layer 41.

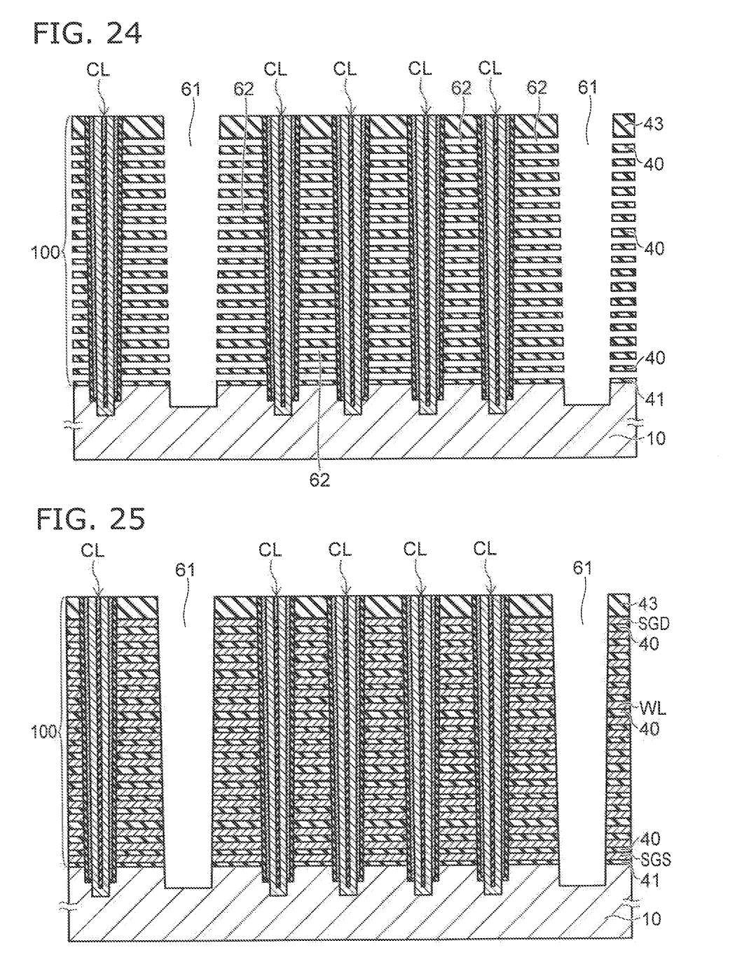

In the spaces 62, as shown in FIG. 25, the electrode layers WL, the drain side select gates SGD, and the source side select gates SGS are formed through the slits 61.

The drain side select gates SGD are formed in the spaces 62 of the top layer. The source side select gates SGS are formed in the spaces 62 of the bottom layer. The electrode layers WL are formed in the spaces 62 between the top layer and the bottom layer.

The electrode layers WL, the drain side select gates SGD, and the source side select gates SGS are metal layers and contain, for example, tungsten.

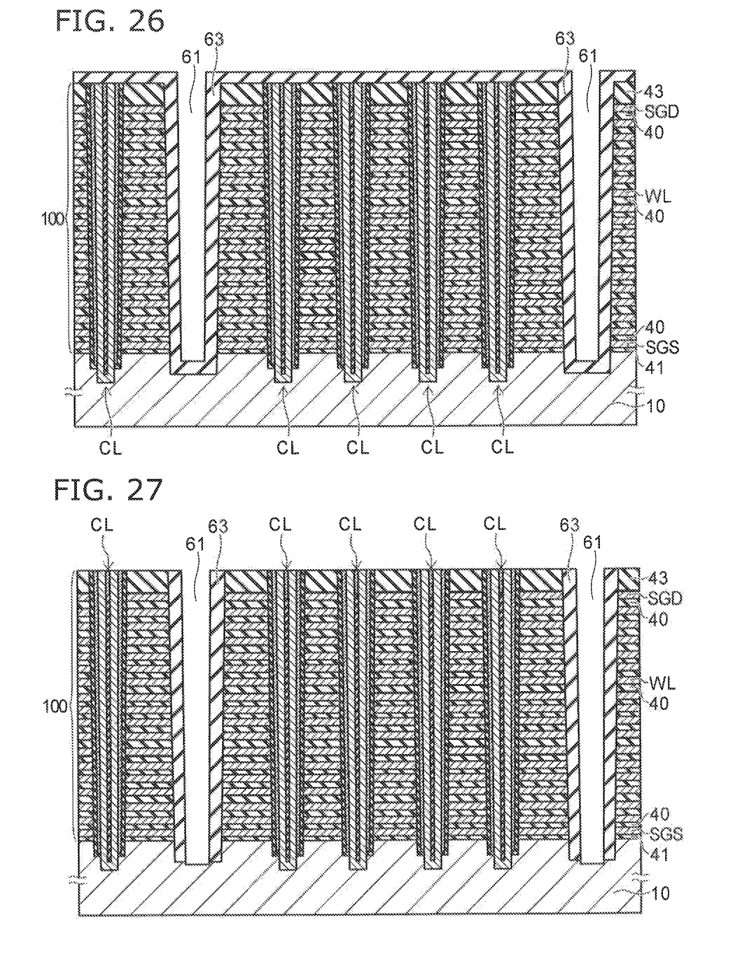

Subsequently, as shown in FIG. 26, insulating films 63 are formed on the inner walls (the sidewalls and the bottoms) of the slits 61. As shown in FIG. 27, the insulating films 63 formed in the bottoms of the slits 61 are removed by RIE method.

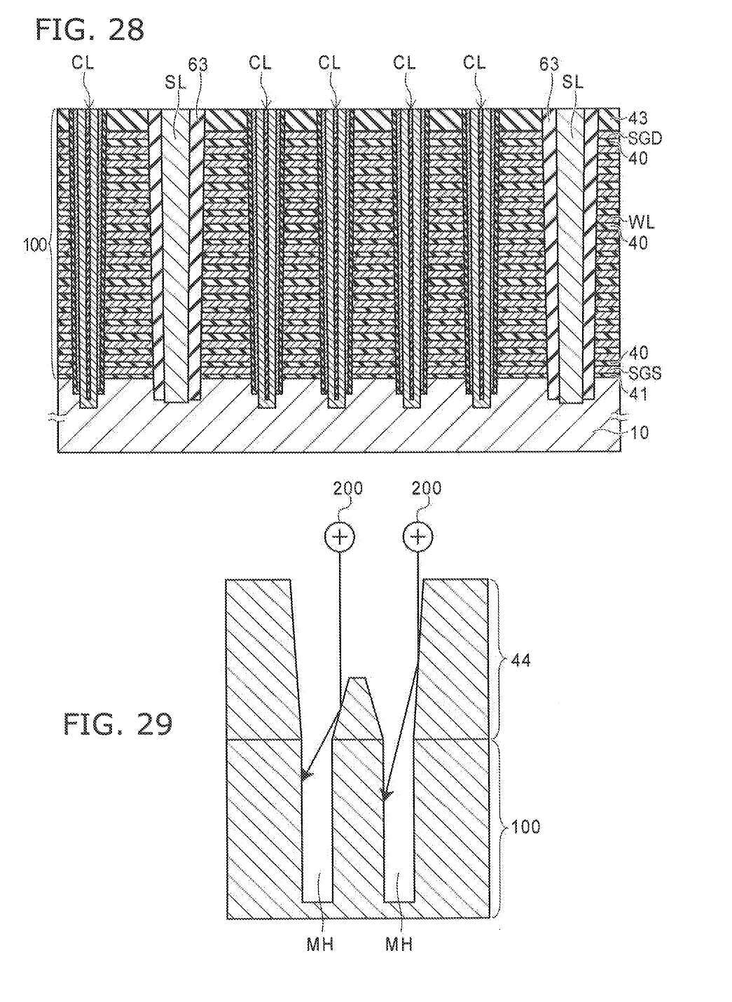

Thereafter, as shown in FIG. 28, the source layers SL are buried in the slits 61. The lower end portions of the source layers SL are connected to the substrate 10. The lower ends of the channel films 20 and the source layers SL are electrically connected via the substrate 10.

Thereafter, as shown in FIG. 1, the drain side select gates SGD are separated in the Y-direction. Further, thereafter, the bit lines BL shown in FIG. 1, upper layer interconnects connected to the source layers SL, and the like are formed.

In the embodiments described above, the etching target layer 100 is not limited to the stacked film formed by alternately repeatedly stacking different types of films and may be a stacked film without a repeated structure or a single layer film of the same type. The embodiments described above are particularly suitable for formation of holes having a high aspect ratio irrespective of the material and the structure of the etching target layer 100.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device comprising:
etching an etching target layer under a mask layer using a first gas, the mask layer including a plurality of first layers, one or more second layers including a second layer provided between adjacent first layers and having a material different from a material of the first layers, and a mask hole piercing through the plurality of first layers and the one or more second layers; and
etching an outermost first layer exposed to an outermost layer of the mask layer among the plurality of first layers using a second gas, and exposing a layer directly under the outermost first layer,
the etching using the first gas and the etching using the second gas being repeated to form a hole in the etching target layer.

2. The method according to claim 1, wherein
a third layer is formed above the mask layer, the third layer having a thickness thicker than a total thickness of the one or more second layers and having a same material as the material of the second layer, and
the mask hole is formed in the mask layer by etching using the third layer as a mask.

3. The method according to claim 1, wherein the first gas is switched to the second gas to etch the outermost first layer when fluctuation occurs in height of an upper surface of the outermost first layer during the etching using the first gas before the outermost first layer disappears.

4. The method according to claim 1, wherein
the first layer contains carbon as a main component,
the second layer contains silicon oxide or silicon as a main component, and
the second gas contains at least any one of oxygen, hydrogen, and ammonium.

5. The method according to claim 1, wherein
the first layer contains silicon as a main component,
the second layer contains silicon oxide as a main component, and
the second gas contains hydrogen bromide.

6. The method according to claim 1, wherein the etching target layer includes a plurality of fourth layers and a plurality of fifth layers including a fourth layer provided between the fifth layers.

7. The method according to claim 6, wherein
the fourth layers contain silicon nitride as a main component,
the fifth layers contain silicon oxide as a main component, and
the first gas contains fluorocarbon or hydro fluorocarbon.

8. The method according to claim 6, further comprising:
forming a slit in the etching target layer;
removing the fourth layers with etching through the slit; and
forming electrode layers in spaces formed by removing the fourth layers.

9. The method according to claim 8, further comprising:
forming a film including a charge storage film on a sidewall of the hole; and
forming a channel film on a sidewall of the film including the charge storage film.

10. A method for manufacturing a semiconductor device comprising:
etching an etching target layer under a mask layer using a first gas, the mask layer including a plurality of first layers, a plurality of second layers including a second layer provided between the first layers and having a material different from a material of the first layers, a first mask hole piercing through the plurality of first layers and the plurality of second layers, and a second mask hole shallower than the first mask hole; and
etching an outermost first layer exposed to an outermost layer of the mask layer among the plurality of first layers and a portion under the second mask hole in a first layer under the outermost first layer using a second gas, and exposing a second layer directly under the outermost first layer and a portion under the second mask hole in a second layer under the second layer directly under the outermost first layer,
the etching using the first gas and the etching using the second gas being repeated to form a hole in the etching target layer under the first mask hole and not form a hole in the etching target layer under the second mask hole.

11. The method according to claim 10, wherein the first mask hole and the second mask hole are cyclically arrayed.

12. The method according to claim 10, wherein
a projected section is formed in a top second layer in the mask layer,
a top first layer is formed on the top second layer to cover the projected section, and
the second mask hole pierces through the top first layer on the projected section and reaches the projected section.

13. The method according to claim 12, wherein
the first mask hole and the second mask hole are formed by etching using a third layer as a mask, the third layer being formed above the top first layer, and
the third layer has a same material as the material of the second layer, and has thickness thicker than a total thickness of the plurality of second layers.

14. The method according to claim 13, wherein the projected section remains under the second mask hole in a state in which the first mask hole pierces through the mask layer.

15. The method according to claim 10, wherein
the first layer contains carbon as a main component,
the second layer contains silicon oxide or silicon as a main component, and
the second gas contains at least any one of oxygen, hydrogen, and ammonium.

16. The method according to claim 10, wherein
the first layer contains silicon as a main component,
the second layer contains silicon oxide as a main component, and
the second gas contains hydrogen bromide.

17. The method according to claim 10, wherein the etching target layer includes a plurality of fourth layers and a plurality of fifth layers including a fourth layer provided between the fifth layers.

18. The method according to claim 17, wherein
the fourth layers contain silicon nitride as a main component,
the fifth layers contain silicon oxide as a main component, and
the first gas contains fluorocarbon or hydro fluorocarbon.

19. The method according to claim 17, further comprising:
forming a slit in the etching target layer;
removing the fourth layers with etching through the slit; and
forming electrode layers in spaces formed by removing the fourth layers.

20. The method according to claim 19, further comprising:
forming a film including a charge storage film on a sidewall of the hole; and
forming a channel film on a sidewall of the film including the charge storage film.
